(19) United States
(12) Patent Application Publication
(10) Pub. No.: US 2018/0122675 A1
(43) Pub. Date: May 3, 2018

(54) SUBSTRATE CARRIER TRANSPORT, SORTING AND LOADING/UNLOADING

(71) Applicant: Tec-Sem AG, Tägerwilen (CH)

(72) Inventors: Gerhard Dovids, Grabs (CH); Yves Fenner, Berg (CH); John Fiddes, Kreuzlingen (CH); Christian Wohanka, Tägerwilen (CH); Bernd Rahrbach, Konstanz (DE)

(21) Appl. No.: 15/791,634

(22) Filed: Oct. 24, 2017

Related U.S. Application Data
(60) Provisional application No. 62/412,252, filed on Oct. 24, 2016.

(51) Int. Cl. H01L 21/677; H01L 21/67; B25J 11/00; H01L 21/673

(52) U.S. Cl. CPC H01L 21/67769; H01L 21/67265; H01L 21/67271; H01L 21/67393; H01L 21/67346; H01L 21/67383; B25J 11/0095

(57) ABSTRACT

A substrate stocker system includes a high-density storage chamber that comprises one or more stacks of one or more substrates in a closed position, one or more substrates being supported on a respective carrier, one or more low density containers, wherein each low density container being configured to store one or more substrates in an open position. The substrate stocker system further includes a first robot configured to move the one or more stacks between the high density storage chamber, and the one or more opener stations, and a second robot configured to move the individual one or more substrates between the one or more opener stations and the one or more low density containers.

This application claims priority from at least U.S. Provisional Patent Application 62/412,252, filed on Oct. 24, 2016 with docket numbers as TSGN-0005P and U.S. Provisional Patent Application 62/355,856, filed on Jun. 28, 2016 with docket number as TSGN-0001P and entitled “Substrate Storage and Processing” which application may be incorporated herein by reference in its entirety for all purposes.

### FIELD OF TECHNOLOGY

This disclosure relates generally to substrates and substrate manufacturing. In one example embodiment, to methods, apparatus, and systems to transfer substrates or wafers from one carrier to another carrier, holder, storage, buffer etc. More specifically the transferring may include sorting or unloading a carrier and placing them in another carrier via a station.

### BACKGROUND

Within many fields, substrates, wafers, etc. must be processed, stored and otherwise moved within a factory, assembly line, or system. Since the introduction of the 300 mm wafer semiconductor material, Front Opening Unified Pods, or “FOUPs,” have become the standard storage and transport method of substrates and similar materials. FOUPs have been used to isolate and hold silicon wafers for use in semiconductor production. Semiconductors, fundamental in the design of digital circuitry, microprocessors, and transistors, require these wafers to remain in as close to immaculate condition as storage units allow. Accordingly, FOUPs allow wafers to be transferred between other machines used in the processing and measurement of wafers.

Prior FOUPs generally serve to preserve wafers from the surrounding clean room environment. In conventional semiconductor projects, FOUPs allow wafers to enter the apparatus via a load port and front opening door. Often, robot handling mechanisms may place the wafers into the FOUP, where they are clamped in place by fins and held for later use. Yet FOUPs today are hampered by methods and system designs which may contaminate their contents, chafe wafers, and delay loading and unloading of substrate wafer contents as a result of multifarious construction. Thus, there is a need for an invention that more efficiently and accurately accomplishes the desired tasks of FOUPs.

The improved Tec-Cell provides this improvement, and as such is to become the new standard in substrate manufacturing. With many advantages over the prior arts and FOUPS, Tec-Cells provide for high density, efficient, clean and resilient processing and capabilities over prior art. However, Tec-Cell systems must work within larger systems and existing infrastructure and as such the new components, systems, buffers, stations, etc. must be made to be able to either through adapters, or otherwise be able to interface with existing systems, carriers etc., of which are mostly FOUPs but may be other designs and standards.

Therefore, a transfer station, system, method and apparatus is necessary that provides improved Tec-Cell designs with an ability to transfer wafers or substrates and groups of wafers or substrates between FOUPS and Tec-Cell systems and apparatuses, as well as transferring substrates and Tec-Cells between bare stockers, processing and manufacturing where the wafer may be removed from the FOUP or Tec-Cell. These processes must be done in an efficient, clean and minimized contaminant manner, as well as provide for little to no downtime or hindrance to process. As well as this, there is a need for other processes to be carried out simultaneously, such as sorting, marking, organizing, or other processes such as purging that can provide for an additional benefit of providing simultaneously. It is clear then these is a need for simultaneously providing higher density wafer and substrate carrying and transferring from these carriers to existing systems and methods where the high density carriers and storages are able to be used efficiently and quickly, including improvements such as tracking, identification, sorting etc. as well as being able to be implemented in existing FOUP systems and other systems.

### SUMMARY

Disclosed are methods, apparatus, and systems that provide transfer ability between substrate systems.

In an embodiment of the present invention, a substrate stocker system is provided that includes a high density storage chamber that comprises one or more stacks of one or more substrates in a closed position, each substrate being supported on a respective carrier, one or more low density containers, wherein each low density container being configured to store one or more substrates in an open position. The substrate stocker system further includes one or more opener stations coupled to the high density storage chamber, and the one or more low density containers, each opener station being configured to receive one or more substrates, and modify one or more distances between one or more adjacent received substrates. The substrate stocker system further includes a first robot configured to move the one or more stacks between the high density storage chamber, and the one or more opener stations, and a second robot configured to move the individual one or more substrates between the one or more opener stations and the one or more low density containers.

In another embodiment of the present invention, a method of storing and transferring substrates in a substrate stocker system is provided. The method includes transferring a stack of substrates from a high density storage chamber to an opener station through a first robot, the transferred stack of substrates being in a closed position; opening the one or more substrates of the transferred stack at the opener station, wherein the stack of the one or more opened substrates are in an open position, and transferring the one or more opened individual substrates to at least one of: a low density container, and one or containers of an Equipment Front End Module (EFEM) coupled to the opener station.

The present invention may provide for an ability to provide in a preferred embodiment for a method or system, such as a transfer station, module or compartment, wherein a FOUP, substrate or wafer carrier, or Tec-Cell may be entered via a robot or other method and may be manipulated by the transfer station such that a bare group or mounted wafer, Tec-Cell or object may be transferred to a station, system, carrier, compartment, Tec-Cell or FOUP.

The transfer station may provide for then transferring wafers, substrates from any combination between FOUPs, Tec-Cell or other carriers. This may be done one by one, or by groups, and may be in any order. One instance may be a transfer between a FOUP and Tec-Cell carriers, where then the Tec-Cells may be then transferred to high density configurations or may be transferred from high density configuration. Another may be such that the transfer incudes wafers in high density Tec-Cell carries be transferred to FOUPs. It is noted this may happen in any direction or order.

It is also apparent that during transfer, other actions may be carried out, such as organization or sorting of the wafers, Tec-Cell, carriers etc. Additionally, purging, quality control, reading, marking and any other actions may be apparent by the transfer station. This may also include wherein Tec-Cells are opened, such that they may be accessed and transferred from high density configuration.

The methods and systems disclosed herein may be implemented in any means for achieving various aspects. Other features will be apparent from the accompanying drawings and from the detailed description that follows.

### BRIEF DESCRIPTION OF THE DRAWINGS

Example embodiments are illustrated by way of example and are not limited to the figures of the accompanying drawings, in which, like references indicate similar elements.

FIG. 1A depicts a side component view of a stocker system, in an embodiment of the present invention;

FIG. 1B depicts a side component view of a stocker system, in an embodiment of the present invention;

FIG. 2A describes a flow chart of a method for storing substrates, in an embodiment of the present invention;

FIG. 2B describes a flow chart of a method for storing substrates, in an embodiment of the present invention;

FIG. 3A depicts a component view of a stocker system, in an embodiment of the present invention;

FIG. 3B depicts a component view of a stocker system, in an embodiment of the present invention;

FIG. 3C depicts a component view of a stocker system, in an embodiment of the present invention;

FIG. 4A describes a flow chart of a method for opening substrates, in an embodiment of the present invention;

FIG. 4B describes a flow chart of a method for closing substrates, in an embodiment of the present invention;

FIG. 5A depicts a top component view of a Tec-Cell stocker, in an embodiment of the present invention;

FIG. 5B depicts a top component view of a Tec-Cell stocker, in an embodiment of the present invention;

FIG. 6A describes a flow chart of a method for transferring substrates, in an embodiment of the present invention;

FIG. 6B describes a flow chart of a method for transferring substrates, in an embodiment of the present invention;

FIG. 7A depicts a top component view of transfer of substrates from stack to opener, in an embodiment of the present invention;

FIG. 7B depicts a top component view of transfer of substrates from stack to opener, in an embodiment of the present invention;

FIG. 7C depicts a top component view of transfer of substrates from stack to opener, in an embodiment of the present invention;

FIG. 7D depicts a top component view of transfer of substrates from stack to opener, in an embodiment of the present invention;

FIG. 7E depicts a top component view of transfer of substrates from stack to opener, in an embodiment of the present invention;

FIG. 7F depicts a top component view of transfer of substrates from stack to opener, in an embodiment of the present invention;

FIG. 7G depicts a top component view of transfer of substrates from stack to opener, in an embodiment of the present invention;

FIG. 7H depicts a top component view of transfer of substrates from stack to opener, in an embodiment of the present invention;

FIG. 8A describes a flow chart of a method for transferring substrates, in an embodiment of the present invention;

FIG. 8B describes a flow chart of a method for transferring substrates, in an embodiment of the present invention;

FIG. 8C describes a flow chart of a method for transferring substrates, in an embodiment of the present invention;

FIG. 9 depicts a top component view of Tec-Cell overhead transfer, in an embodiment of the present invention;

FIG. 10A describes a flow chart of a method for transferring substrates, in an embodiment of the present invention;

FIG. 10B describes a flow chart of a method for transferring substrates, in an embodiment of the present invention;

FIG. 11A depicts a top component view of Tec-Cell transfer in an embodiment of the present invention;

FIG. 11B depicts a top component view of Tec-Cell transfer in an embodiment of the present invention;

FIG. 12A depicts a top component view of Tec-Cell transfer with robot, in an embodiment of the present invention;

FIG. 12B depicts a top component view of Tec-Cell transfer with robot, in an embodiment of the present invention;

FIG. 13 describes a flow chart of a method for transferring and loading substrates, in an embodiment of the present invention;

FIG. 14 describes a flow chart of an embodiment method for transferring and loading substrates with different containers, in an embodiment of the present invention;

FIG. 15A depicts a top component view of Tec-Cell transfer with robot and removable components, in an embodiment of the present invention;

FIG. 15B depicts a top component view of Tec-Cell transfer with robot and removable components, in an embodiment of the present invention;

FIGS. 16A, 16B and 16C are profile views of a Tec-Cell, in an embodiment of the present invention;

FIGS. 17A, 17B, 17C and 17D are profile views of a Tec-Cell, in an embodiment of the present invention;

FIGS. 18A, 18B and 18C are profile views of a Tec-Cell, in an embodiment of the present invention;

FIGS. 19A and 19B are profile views of a Tec-Cell, in an embodiment of the present invention;

FIGS. 20A, 20B and 20C describe a flow chart of a method for transferring and loading substrates, in an embodiment of the present invention;

FIGS. 21A, 21B, 21C and 21D describe in a side component view of a ceiling system, in an embodiment of the present invention; and

FIGS. 22A, 22B, 22C and 22D describe a flow chart of an embodiment of the present invention ceiling system.

Other features of the present embodiments will be apparent from the accompanying drawings and from the detailed description that follows.

### DETAILED DESCRIPTION OF THE EMBODIMENTS

Disclosed are methods, apparatus, and systems that may provide in one example embodiment, to methods, apparatus, and systems to transfer substrates or wafers from one carrier to another carrier, holder, storage, buffer etc. More specifically the transferring may include sorting or unloading a carrier and placing them in another carrier via a station.

In an embodiment, which may be combined with any other embodiment, the present invention may provide for a substrate storage or stocker including further methods, apparatuses, systems and subsystems, and devices mentioned herein at the least.

In an embodiment, which may be combined with any other embodiment, the present invention described may provide for a stocker or storage system for wafers and other substrates for any purpose such as manufacturing, processing or storage. In a preferred embodiment, the stocker may include a chamber, wherein the substrates are stocked or stored. Within this chamber, may be any number of compartments of which may include at least one wafer, but also may be a stack of wafers. The wafers may be bare in the compartments, or may be held in containers, and preferably each or groups of wafers are supported on substrate carriers.

In an embodiment, which may be combined with any other embodiment, the present invention described may provide high density storage containers and transport related applications. In an example, high density or collapsed Tec-Cells with wafers are provided, and wherein the Tec-Cells are opened, such that they may be accessed and transferred.

In an embodiment, which may be combined with any other embodiment, the invention described may provide a container that may include a container body, which surrounds the wafers from at least three sides, container shelves, and a container door at bottom or at side, to access the contents of the container body. Examples of the container include, but are not limited to, a FOUP, a container with an OHT handle for an overhead transport system, and a compartment in a storage chamber or stocker.

In an embodiment, which may be combined with any other embodiment, the invention described may provide that the compartments and containers may be able to be manipulated, moved or opened by robots, or by Overhead Transfer (OHT) systems or by Equipment Front End Module (EFEM) system. It is noted that the robots may be any types of robots, but may include Overhead mounted robots, arm mounted robots, robot with effectors, and conveyors.

In an embodiment, which may be combined with any other embodiment, the invention described may provide for a method or system, such as a transfer station, module or compartment, wherein a FOUP, substrate or wafer carrier, or Tec-Cell may be entered via a robot or other method. The transfer station may provide for then transferring wafers, substrates from any combination between FOUPs, Tec-Cell or other carriers. This may be done one by one, or by groups, and may be in any order. One instance may be a transfer between a FOUP and Tec-Cell carriers, where then the Tec-Cells may be then transferred to high density configurations. Another may be such that the transfer incudes wafers in high density Tec-Cell carriers be transferred to FOUPs.

In an embodiment, which may be combined with any other embodiment, the invention may provide an opener within the transfer station for opening high density Tec-Cell pods, and other containers, wherein the opener may at least provide an effector that may match the container or use. In some embodiments, the effector may be configurable and the opener has a configurable opener pitch to adapt to multi wafer end effectors.

In an embodiment, which may be combined with any other embodiment, the invention may provide one or more robots within the transfer station for transferring stack of high density substrates from the containers to the opener stations, and for transferring low density substrates from the opener stations to external containers such as FOUPs. Within the chamber or sub-chamber may be at least one opening station, wherein wafers, stacks of wafers, compartments or containers may be moved by at least one robot, and wherein there is a described ability to separate or open the substrates, such that the substrates or wafers may be removed or placed in the stack. There, then may be an additional robot which may provide wafers, stacks of wafers, or compartments or chambers to the opener station to be opened, and of which may source from containers such as FOUP's.

In an embodiment, which may be combined with any other embodiment, the present invention may provide for a substrate stocker and a transfer station, with a method, in which FOUPs may be loaded to an Equipment Front End Module (EFEM) load station. The EFEM includes a loading station for a low density container and a loading station for a high density container, wherein the EFEM comprises a robot for individual substrate handling at the low density container and a robot for substrate stack handling at the high density container, and wherein the EFEM is configured to interface with one or more opener stations. The EFEM load station may provide for robust, fast and efficient loading capabilities with limited or no contaminant sources. Then, a robot in EFEM may pick up wafers from one or more FOUPs to one or more opener stations. An opener station may then collapse the wafers, to form a dense stack of wafers, to allow a small spacing between wafers that may be significantly less than that of a SEMI standard. At least one other robot in the stocker may pick up the whole dense stack and place the stack on Tec-cell carriers in a container of a storage. As well as this, the robots may interact with the FOUP's, Tec-Cell carriers, or substrates via any known method. Also in some embodiments, there may be multiple opener stations and any plurality of openers or robots.

In an embodiment, which may be combined with any other embodiment, the present invention may provide that the EFEM may be different for different type of containers and FOUPs, etc. such that the EFEM may match the intended use, or may be actively able to adapt to use with different containers. This is also to be noted to be used as a broader ability than OHT and may supplement, be instead of OHT, among other methods or systems.

In an embodiment, which may be combined with any other embodiment, the present invention may provide for a substrate stocker with a method, in which stacks of high density substrates may be loaded in containers of a storage chamber. Then, a storage robot may pick up one or more stacks from one or more containers, and transfer to one or more opener stations of fixed or adjustable pitches. An opener station may separate a stack of Tec-Cell to allow a large spacing between each wafers, for example, 10 mm. At least one other robot in the stocker may pick up one or more wafers from the opener stations, and place them in one or more external containers such as FOUPs.

It is also apparent that during transfer, other actions may be carried out, such as organizing or sorting of the wafers, Tec-Cell, carriers etc. The sorting of substrates may take place between two opener stations or between an opener station and container, such as a FOUP, stocker, etc. It may be noted that this movement of wafers for sorting may be done by any robot, in any order or in any process, and the wafers may move between any plurality of positions, stacks and directions. In an embodiment, the sorter may sort a wafer by moving respective carrier. Further, sorting can be done only for wafers that are in an open state in respective stack. Additionally, purging, quality control, reading, marking and any other actions may take place at the transfer station.

In an embodiment, which may be combined with any other embodiment, the present invention may provide a stocker system that comprises an operator loading station and an automatic loading station for transferring containers. The operator loading station is a port/terminal which may be accessible by human manual entry. The operator loading station is a port which may be accessible by a machine transfer mechanism for transferring individual substrates.

In an embodiment, which may be combined with any other embodiment, the present invention may provide for a transfer station where the EFEM, opener stations and robots, may sort or otherwise provide an operation such as organizing, sorting, grading or otherwise moving or choosing substrates, carriers, or groups by some method, whether it be known placement, such as from identifiers on the individual carriers, substrates or pieces, of which may be physical, wireless, or wired markers and connect to a database, or via inspection of the objects through any method.

In an embodiment, which may be combined with any other embodiment, the present invention may provide a transfer station that may take a combination of FOUPs and Tec-Cells, including Tec-Cell containers, and combine them. This may also be done with like containers such as only Tec-Cell containers and compartments being transferred into one. In an example, two or more sets of substrates may be consolidated to form and store a combined stack of substrates in a high density container, wherein the combined stack of substrates has a pitch smaller than that of the two or more sets of substrates.

In an embodiment, which may be combined with any other embodiment, the present invention transfer station may be on the ground floor. In other embodiments, it may be ceiling based. It is noted that the transfer station may be standalone or a compartment on a larger system or apparatus. The ceiling based transport mechanism includes a distributed OHT track system which is formed of a main OHT track, and one or more branch tracks for storing and transporting one or more high density Tec-Cell containers/FOUPs.

In an embodiment, which may be combined with any other embodiment, the present invention may provide for a transfer station that may provide for purging at any point of the system, such as to provide for less contamination, and may be used between wafers. There may be individual storage containers, with doors and individual wafer purge, as well as sectional or system based. It is noted the stocker system may include purging at any level of the system, such as system wide, chamber wide, or at each individual compartment, or wafer. In an example, herein, N2/NO gas may be used for purging, and may be configured to reach each container and substrate equally through laminar flow. Various parameters such as purge gas temperature control, purge time/before, during, after closing, recovery times, high flow/low flow may be set for the laminar flow of purge gas. The transfer station may include airlocks, and other features providing to not requiring clean room environment.

In an embodiment, which may be combined with any other embodiment, the present invention may provide for a transfer station, wherein the substrate stocker or stocker includes at least one of an Integrated Overhead transport (OHT) system in storage, and EFEM for FOUP and Tec-Cell Carriers. In an embodiment, which may be combined with any other embodiment, the present invention may provide for an EFEM for FOUPs and Tec-Cell carriers of which may link the present stocker and other processing stations. This EFEM may accept FOUPs and Tec-cell carriers with the opener as an option.

In an embodiment, which may be combined with any other embodiment, the present invention may provide for a transfer station where the Tec-Cell carriers or FOUPs may be carried, manually or via other methods directly to storage.

In an embodiment, which may be combined with any other embodiment, the present invention may provide any method, system or apparatus of transfer mechanism for the FOUPs, Tec-Cell carriers or substrates of which may include Zero Footprint solution, such as ceiling, above floor or sub-floor conveyors, robots or arms.

In an embodiment, which may be combined with any other embodiment, the present invention may provide a method to provide for high density storage, of which may include features such as protection by N2/XCDA/NO and other gases in confined environment, stack ability for space constraints and density, modularity, and floor and ceiling mounts and mounting systems including transporters. In addition, the architecture of the system may include at least a storage in Tec-Cell and Transfer module, among other modules and features which allow for not requiring a clean room environment.

In an embodiment, which may be combined with any other embodiment, the present invention may provide Transfer Module which provide for moving wafers from FOUPS to Tec-Cells (Zoom Pods) manually or automatically, and may provide for the ability to have different or adjustable, either manually or automatically, opener design, pitch and ability of which may adapt to multi wafer end effectors. In addition, the stocks and towers may be automatically or manually, of which may align the stocks, and read the alignment well as stacks, both for proper placement, organization, sorting etc.

In an embodiment, which may be combined with any other embodiment, the present invention may provide a method where in the Tec-Cell stack, individual modules, or individual substrates may include an electronic tracking device that may detect, store, communicate parameters such as humidity, temperature, shock, charge, stack ID of the stacks, and may present information in any method or device wired or wirelessly or optical based, such as via IR, RFID, photo based such as barcode or QR code, wired, or any other method.

In an embodiment, which may be combined with any other embodiment, the present invention may provide an improved Stocker Management system (SSCMS) that may work with a Manufacturing Execution System (MES) and Material Tracking System (MTS) as well as communicate and network with other exterior or internal systems or 3^{rd} party proprietary software through local intranet or internet.

In an embodiment, which may be combined with any other embodiment, the present invention may provide ESD wafer optimized ionization and de-ionization for further quality control as well as improved seal and transfer systems and methods, depending on the application and substrates or objects being held. This may be carried out at any point of the storage or transfer, and may also be actively provided either on an individual wafer or on a compartment basis, section basis, such as each Tec-Cell or FOUP, or on a system wide base.

In an embodiment, which may be combined with any other embodiment, the present invention may include an aforementioned Tec-Cell stack “Zoom” module which may provide for increased wafer density for storage. An increase in wafer density increases transportation system throughput of single and multi-wafer delivery, reduces footprint, shortens wait time, and improves efficiency of transfer, production and processing.

In an embodiment, which may be combined with any other embodiment, the present invention may provide a Fab Level and Load/Unload ability in the T3k-Cell/Zoom Modules, of which may include new load ports, ZOOM/FOUP port loader, of which may all be Zoom capable. Additionally, the T3k-Cell/Zoom and associated devices and systems may include AHMS adapter/transport, Zoom adapter and any other adapters and abilities, such as a bottom or top plate which may be structured like FOUP bottom/top plate for the adapters.

In an embodiment which may be combined with any other embodiment, the present invention may provide where the Zoom modules may be powered, non-powered, RF powered, wireless charged as well as incorporate communication between Zoom pods to hasten movement, efficiency and fulfill internal system movements and requests in a clean, safe, and organized fashion. Many of the wireless communication may be done via RFID devices within the system, and of which may be third party or proprietary design.

In an embodiment which may be combined with any other embodiment, the present invention may provide for a method or system, which may be combined with any other embodiment, the present invention may provide the ability of an improved storage and wafer transfer system that may provide maximum utilization and on time delivery of wafers to process tools.

It is noted that throughout the spec, when a carrier, substrate, container, stack, etc. are mentioned to be configured, moved, organized, effected or otherwise provided, they may be interchange for one another. For instance, in an embodiment, instead of a container with carriers and substrates being moved from a high density storage compartment to an opener, in an embodiment, instead of a container being moved, it may be a bare stack of carriers and substrates, or even just substrates, or even empty carriers. It is especially noted that the carriers may be empty in any embodiment, or wherein the containers are empty to be repositioned or for any other reason.

In an embodiment which may be combined with any other embodiment, the present invention may provide a substrate stocker system, wherein the system includes a high density storage chamber that comprises one or more high density containers or stacks of one or more substrates, each substrate being supported on a respective carrier wherein the high density containers or stacks are in a closed position. It is noted that the one or more low density containers may be such that each low density container is configured to store one or more substrates and carriers such as FOUPs.

In an embodiment which may be combined with any other embodiment, the present invention may provide one or more opener stations wherein each opener station is configured to send or receive one or more stacks or containers from at least one high density storage chamber and one or more substrates from the low density containers. It is noted that each opener station may comprise one or more separator modules for changing one or more distances between corresponding one or more adjacent substrates in the high density containers or stacks.

In an embodiment which may be combined with any other embodiment, the present invention may provide at least one robot wherein the one or more robots are configured to move one or more containers or stacks between the high density storage chamber, and the one or more opener stations; and one or more substrates between the one or more high density open position high density containers or stacks and the one or more low density containers.

It is noted that the system itself may be isolated from an ambient atmosphere, and may internally isolate different stations, compartments and areas from others, such that the atmosphere stays clean to reduce contamination. It is noted that purge gas may be introduced to any area, to aid in cleanliness, especially after transferring to provide for less contamination for the substrates for reduced damage.

In an embodiment which may be combined with any other embodiment, the present invention may provide for one or more distances between one or more adjacent substrates of the one or more stacks in the closed position, is less than a threshold distance defined by Semiconductor Equipment and Materials International (SEMI) standard.

In an embodiment which may be combined with any other embodiment, the present invention may provide at least one OHT system, and one or more OHT stations for moving one or more movable high density containers with the OHT, between the high density storage chamber and external to the stocker system as well as other stockers and processors or within the stocker itself, such as to change or move between stations.

In an embodiment which may be combined with any other embodiment, the present invention may provide wherein container load port may configured to receive and store at least movable container with the OHT, wherein there may be at least one robot configured to transfer the movable container with the OHT, from the container load port to the high density storage chamber.

In an embodiment which may be combined with any other embodiment, the present invention may provide part of or a different OHT system, for moving one or more low density containers to and from the stocker system.

In an embodiment which may be combined with any other embodiment, the present invention may provide an Equipment Front End Module (EFEM) which may be coupled to the one or more opener stations, wherein at least one robot is disposed within the EFEM module for moving one or more substrates and carriers from an open position high density carrier, between the one or more opener stations, and the one or more low density containers.

In an embodiment which may be combined with any other embodiment, the present invention may provide for the EFEM module wherein there may be one ore mores robot for transferring a movable container with the OHT from a container load port to the high density storage chamber.

In an embodiment which may be combined with any other embodiment, the present invention may provide one or more robots that are configured to access the movable container by opening a side of the container at the container load port, and transfer carriers and substrate stack to an opener station.

In an embodiment which may be combined with any other embodiment, the present invention may provide an operator loading station configured to enable transfer of one or more substrates and carriers to and from the one or more opener stations; and an automatic loading station configured to enable automatic transfer of one or more substrates and carriers to and from the high density storage chamber.

In an embodiment which may be combined with any other embodiment, the present invention may provide that the substrates and carriers entered into the operator or automatic loading station are in high density containers in an open position.

In an embodiment which may be combined with any other embodiment, the present invention may provide wherein the substrates and carriers entered into the operator or automatic loading station are in high density containers in a closed position.

In an embodiment which may be combined with any other embodiment, the present invention may provide a purged enclosure mounted on a ceiling therein, wherein the purged enclosure comprises a distributed OHT tracker system that has a main OHT track and one or more branch tracks for storing one or more movable containers.

In an embodiment which may be combined with any other embodiment, the present invention may provide a method of storing and transferring substrates in a substrate stocker system.

The method may then additionally comprise transferring a first closed stack or container of one or more carriers and substrates to or from a high density storage chamber and at least one opener station by an at least one robot; wherein the system may provide opening or closing the stack or container at the opener station, wherein opening increases the distances between each carrier and substrate and closing decreases the distances between each carrier and substrate; and transferring the one or more opened individual substrates to or from at least one of: a low density container, one or containers of an Equipment Front End Module (EFEM), or an external dock cart.

It is noted that the method may then also include moving a movable high density container to or from a container load port and an opener by an at least one robot; wherein then opening or closing the moveable container and then transferring a stack or individual carries and substrates to or from the first high density container and the moveable high density container;

In an embodiment which may be combined with any other embodiment, the present invention may provide sorting one or more substrates within the respective stack or container by moving the one or more substrates among one or more positions within the stack at any point and by any robot or opener station. Additionally, in an embodiment which may be combined with any other embodiment, the present invention may provide sorting one or more carriers and substrates or stacks by changing the position when transferring the carriers and substrates or stacks between the first high density container and the moveable high density container.

It is noted that in an embodiment, the system may then provide moving a movable high density container from a container load port to high density storage chamber by at least one robot.

In an embodiment which may be combined with any other embodiment, the present invention may provide then combining a first stack of carriers and substrates and a second stack of carriers and substrates from at least one of: a low density container, one or containers of an Equipment Front End Module (EFEM), a high density container or an external dock cart to form a combined stack, wherein the combined stack has a pitch smaller than pitches of each of the first and second stacks; and wherein the combined stack is in at least one of: a high density movable container to be moved by OHT or via a container load ports to a dock cart or external system, or a high density container to be stored in the high density storage chamber.

It is noted then that the method may include at least forming a distributed OHT track stocker system for storing high density containers, wherein the distributed OHT track stocker system is formed within a purged enclosure mounted on a ceiling therein; and transferring a high density container from the high density storage area to a distributed OHT track system.

Although the present embodiments have been described with reference to specific example embodiments, it will be evident that various modifications and changes may be made to these embodiments without departing from the broader spirit and scope of the various embodiments. It should be understood by one of ordinary skill in the art that the terms describing processes, products, elements, or methods are industry terms and may refer to similar alternatives. In addition, the components shown in the figures, their connections, couples, and relationships, and their functions, are meant to be exemplary only, and are not meant to limit the embodiments described herein.

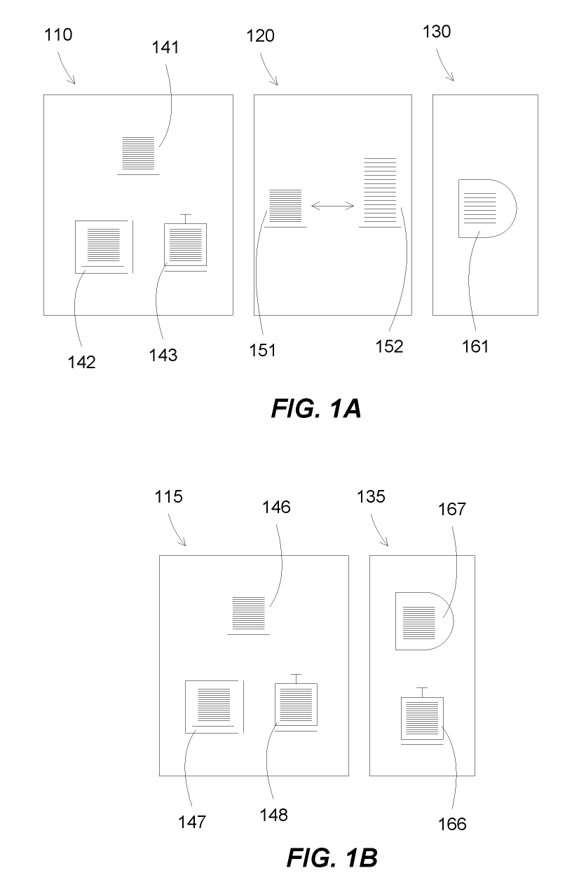

FIG. 1A depicts a side component view of a Tec-Cell stocker, in accordance with an embodiment of the present invention. The Tec-Cell stocker is a stocker system that has a high density storage chamber with a conventional loader station or a high density loader station, wherein the loading may be provided in a transport station.

The Tec-Cell stocker includes a storage chamber 110 that stores one or more Tec-Cells or FOUPS such as a first stack 141 of substrates, a second stack 142 of substrates in a container with a side door and a third stack 143 of substrates in a container with a bottom door or an Overhead Transfer Vehicle (OHT).

An adjacent chamber 120 is an opener station that depicts a stack 151 in a collapsed configuration and a second stack 152 in an open configuration. It may be noted that the open configuration allows for easy access of substrates, and the collapsed configuration optimizes storage space constraints. In an embodiment, the stacks in the open configuration may be transferred to a third chamber 130 from the second chamber 120. The third chamber 130 depicts a loader station for a conventional FOUP 161 in an open configuration.

FIG. 1B depicts a side component view of a Tec-Cell stocker, in accordance with another embodiment of the present invention. In some embodiments, the present invention discloses stocker systems, having a high density storage chamber 115 with a conventional loader station or a high density loader station. The storage chamber 115 may include a first stack 146 of substrates, a second stack 147 of substrates in a container with a door and a third stack in a container with an OHT 148. The Tec-cell stocker 100 further includes a second chamber 135 that stores a FOUP 167, and a stack with the OHT 166. The storage chamber 135 thus, includes high density containers in collapsed configuration. It would be apparent to a person of ordinary skill in the art, that a plurality of stacks may be held in any configuration in any of the first and second storage chambers. A transfer station (not shown) and robot (not shown) may provide the ability to provide the wafers such that they may be mounted in any of the aforementioned forms and in between the aforementioned forms.

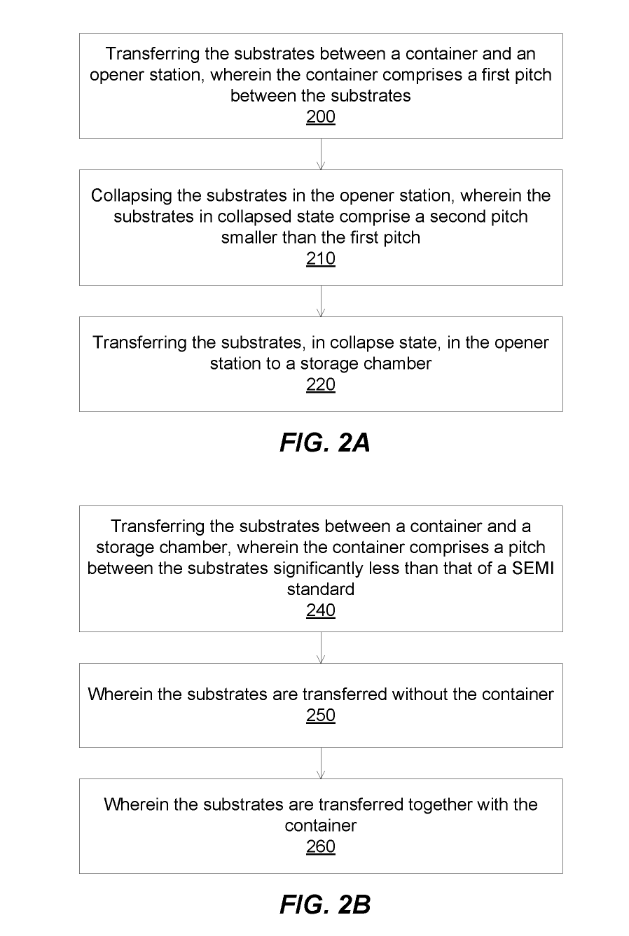

FIG. 2A describes a flow chart of a method for storing substrates in a stocker system such as a Tec-cell stocker, in an embodiment of the present invention. Step 200 describes transferring the substrates between a container and an opener station of the stocker system. The container generally refers to a movable compartment that stores a stack of substrates, and the opener station is a compartment where opening of collapsed substrates take place. Generally, in a stack, each substrate may be separated from an immediately adjacent substrate by respective gaps. The magnitude of these gaps is referred to as the ‘pitch’.

In an embodiment, a substrate stack of the container may have a first pitch. In one embodiment, the pitch of the opener station may be similar to the first pitch or may be different from the first pitch, to suit for different structures and designs, to match a particular object such as a wafer, and to couple to a robot of any type.

Step 210 describes collapsing the substrates of the substrate stack in the opener station, wherein the substrates in the collapsed state has a second pitch smaller than the first pitch. Step 220 describes transferring the substrates in the collapsed state, from the opener station to a storage chamber of the stocker system.

It would be apparent to one of ordinary skill in the art that the steps 208-210 may be performed in any order, and in fact they can be performed in a reverse order to bring substrates from the storage chamber to a loader station. Additionally, it would be apparent to one of ordinary skill in the art, that there may be a number of intermediary steps between the afore-mentioned steps 208-210, as well as some additional steps. Examples of the intermediary and additional steps include, but are not limited to, transferring supports with substrates, transferring a whole stack of substrates at once, placing stack in a container, opening door for containers, etc. The storage chamber store may include stacks, compartments, compartments with doors, etc.

FIG. 2B describes a flow chart of a method for storing substrates in a stocker system such as a Tec-Cell stocker, in an embodiment of the present invention.

Step 240 describes transferring the substrates from a container to a storage chamber, wherein a pitch of the substrates of the container is significantly less than that of a SEMI standard. Step 250 describes transferring the substrates to the storage chamber without the container and step 260 describes transferring the substrates to the storage chamber, together with the container.

In an example, the container is a Tec-Cell specific container that has a small pitch, less than 5 mm, for example, 1, 2, 3, 4, or 5 mm, which may be smaller than the semi-standard which may be 10 mm. It is noted though that an embodiment may use generic FOUP's and Tec-Cells with standard pitches, and any other type of container. Additionally, an embodiment may use different types of containers simultaneously, or for different purposes such as for example stockers using two types of loader stations, such as FOUP for operator and high density container for OHT.

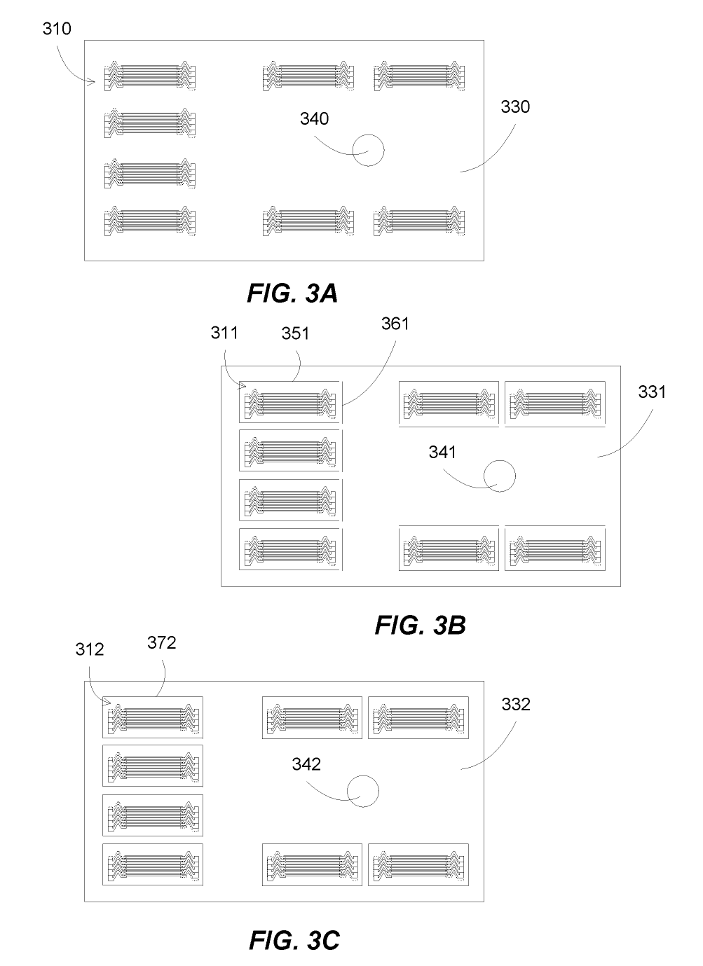

FIG. 3A depicts a component view of a Tec-Cell stocker system, in embodiment of the present invention. The Tec-Cell stocker includes a storage chamber 330 that includes one or more stacks 310 of wafers either supported on carriers such as Tec-cell carriers or stored in FOUPs. The storage chamber 330 further includes a robot 340 which may be configured to move one or more wafers, or one or more stacks as whole from one position to another in the storage chamber 330. In an embodiment of the present invention, each stack 330, in general has the ability to provide purge gas.

Purging gas is already a known feature for providing clean conditions in a storage chamber of the stocker systems. In an example, herein, N2 gas may be used for purging, and configured to reach each container and substrate equally through laminar flow.

FIG. 3B depicts a component view of a Tec-cell stocker in accordance with another embodiment of the present invention. The Tec-cell stocker includes a storage chamber 331 which includes one or more movable containeres 311, each with a container body 351 and a container door 361. Each movable container 311 may store stacks of wafers, Tec-cells or FOUPs. In an embodiment, the one or more containers 311 may be removed from the storage chamber 331 through a robot 341. In an embodiment, the robot 341 may either move a whole container 311 or individual contents/substrates of the container 311 from one location to another. The robot 341 may have an arm to open a container door (look ahead to open door before it reaches containers) and a sensor to open door when the robot 341 approaches the door. In another embodiment of the present invention, each container 311, in general has the ability to provide purge gas for preventing contamination in the storage chamber 331.

FIG. 3C depicts a component view of a Tec-Cell stocker, in accordance with an embodiment of the present invention. The Tec-Cell stocker includes a storage or stocker chamber 332, which may include a one or more stacks of Tec-cells or wafers 312 within one or more containers 372. In an embodiment, the containers 372 may have shelves, or side doors or bottom doors (like FOUP). The storage chamber 332 may include a robot 342 to move a whole container 372 or individual contents/substrates of the container 372 from one location to another. In another embodiment of the present invention, each container 311, in general has the ability to provide purge gas for preventing contamination in the storage chamber 332.

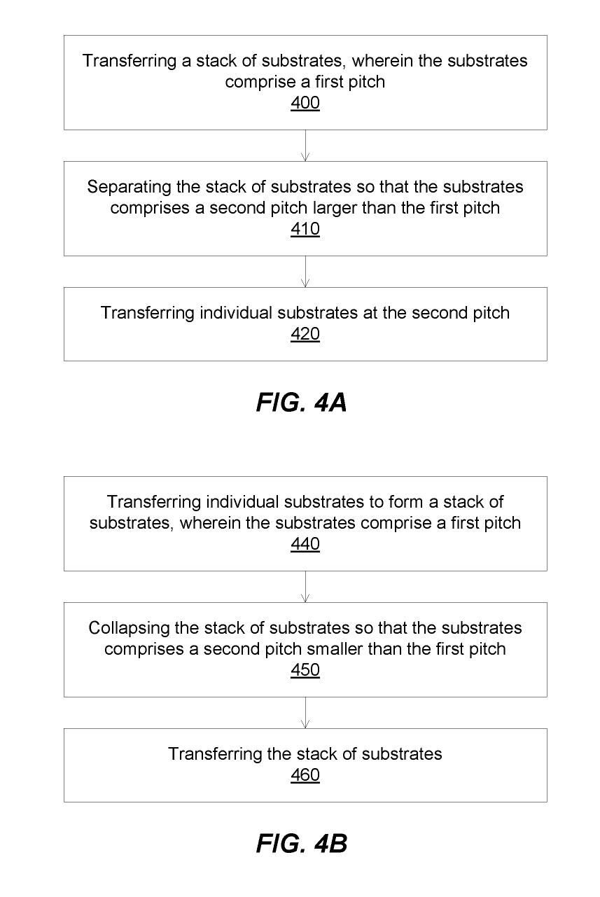

FIG. 4A describes a flow chart of a method for opening substrates in an opener station of a stocker system such as Tec-Cell stocker system, in accordance with an embodiment of the present invention. Wherein as described in an embodiment, step 400 includes transferring a stack of substrates to an opener station from, for example, a storage chamber, wherein the stack of substrates comprise a first pitch. Step 410 includes separating/opening the stack of substrates by increasing the gap between the adjacent substrates, so that the stack of separated substrates comprise a second pitch larger than the first pitch. Step 420 includes transferring individual substrates at the second pitch from the opener station to a low density loading station.

It may be apparent to one of ordinary skill in the art that the pitch may be variable, for exposing one or more substrates, and to allow for possible batch transfer, or single substrate transfer, in low as well as high density stacks.

FIG. 4B describes a flow chart of an embodiment method for closing substrates in a Tec-Cell stocker system, in accordance with an embodiment of the present invention. Step 440 includes transferring individual substrates to form a stack of substrates, wherein the stack of substrates comprises a first pitch. Step 440 includes collapsing/closing the stack of substrates by decreasing gap between adjacent substrates, so that the stack of collapsed substrates have a second pitch smaller than the first pitch. Finally, step 460 includes transferring the stack of collapsed/closed substrates. In an embodiment, the stack of closed substrates may be transferred to a storage chamber of the Tec-Cell stocker system.

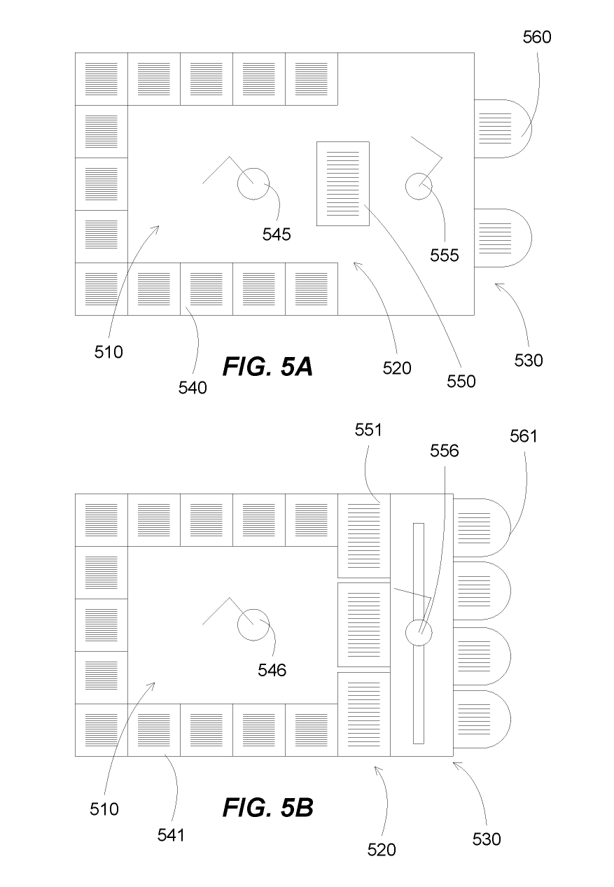

FIG. 5A depicts a top component view of a Tec-Cell stocker system, in an embodiment of the present invention. The Tec-Cell stocker system includes a storage chamber 510 that includes one or more high density containers 540, each with a door for storing a stack of collapsed/closed substrates, a first robot 545 to move a stack from a container 540 to an opener station 520 for generating an opened stack 550 of substrates. In the open state, the individual substrates/wafers of the stack 550 may be moved by a second robot 555 from the opener 550 to other containers 560 such as FOUPs with a load port 530. It will be apparent to a person of ordinary skill in the art that the first and second robots 545 and 555 may be configured to move between the one or more stacks, or move between the one or more containers 560, or perform a reverse process of filling up the storage chamber 520 with stacks of collapsed substrates.

FIG. 5B depicts a top component view of a Tec-Cell stocker in an embodiment of the present invention. The Tec-Cell stocker includes a storage chamber 510 that includes, one or more containers 541 with door, at least one robot 546 to move at least one stack from the containers 541 to at least one of multiple opener stations 520, and at least one Equipment Front End Module (EFEM) coupled to the load port 530 includes an EFEM robot 556 to move one or more opened wafers 551 from the one or more opener stations 520 to one more other containers 561 such as FOUPs with a load port 530.

It is noted in this figure and embodiment, and in any other figure and embodiment, there may be any order or any plurality of individual stations, structures, robots etc.

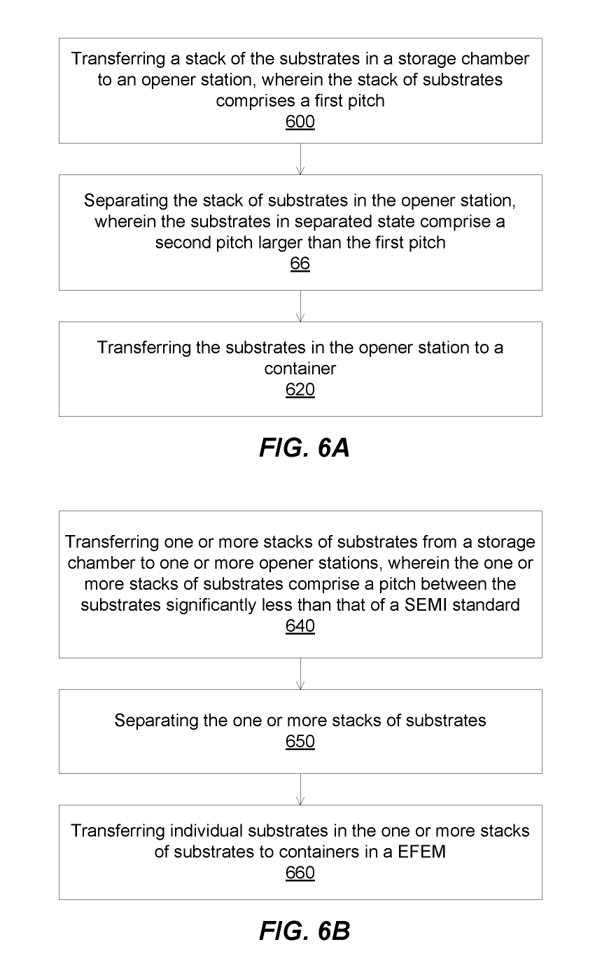

FIG. 6A describes a flow chart of an embodiment method for transferring individual substrates in a Tec-Cell stocker system. Step 600 includes transferring a stack of the collapsed/closed substrates from a storage chamber to an opener station, wherein the stack of closed substrates comprises a first pitch. Step 66 includes separating/opening the stack of substrates in the opener station by increasing the gap between corresponding adjacent substrates, such that the substrates in the separated state have a second pitch larger than the first pitch. Process 620 describes transferring the separated substrates from the opener station to a container such as FOUP.

FIG. 6B describes a flow chart of an embodiment method for transferring individual substrates in a Tec-cell Stocker system. Step 640 describes transferring one or more stacks of closed substrates from a storage chamber to one or more opener stations, wherein the one or more stacks of closed substrates has a pitch that is significantly less than that of a SEMI standard. Step 650 describes separating the substrates of the one or more stacks by increasing gaps between corresponding adjacent substrates. Step 660 describes transferring individual substrates of the one or more stacks to containers such as FOUP through an EFEM robot.

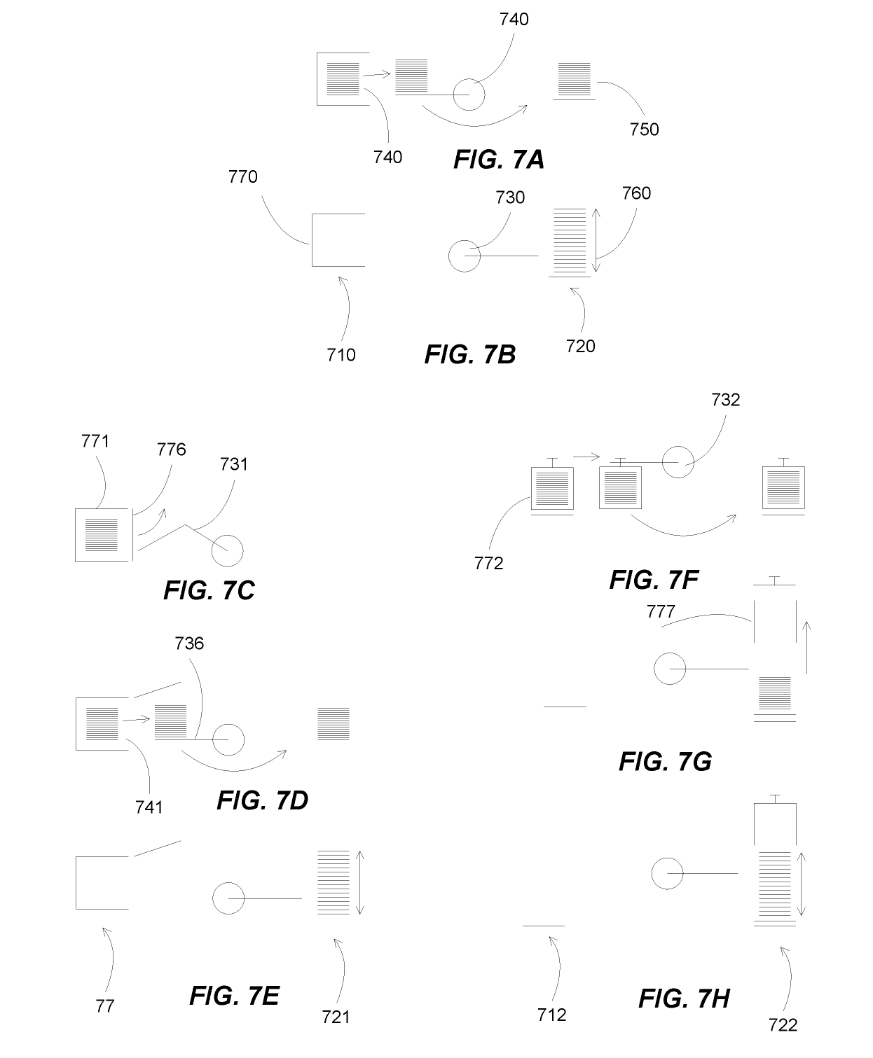

FIG. 7A and 7B depict component views of transfer of a stack of substrates in a Tec-Cell stocker, in an embodiment of the present invention. FIG. 7A describes a transfer of the stack of substrates from a container 740 to an opener station 750 through a robot 740, wherein, at the opener station 750, the substrates are in a closed state. FIG. 7B shows then an empty container 710 with a side door 770, wherein a robot 730 had transferred the stack to opener station 720, that includes a stack of substrates separated by a distance or separation 760.

FIG. 7C, 7D and 7E depict top component views of transfer of a stack of substrates in a Tec-Cell stocker, in an embodiment of the present invention. Wherein, FIG. 7C shows a container 771 with a door 776, that may be opened by a robot 731 with an effector. FIG. 7D shows then the stack 741 of closed substrates, being removed from the container 771 by the robot with effector 736, for transfer to an opener station, and then FIG. 7E displays an empty container 77 and a stack 721 in an open state.

FIG. 7F, 7G and 7H depict top component views of transfer of a stack of substrates in a Tec-Cell stocker, in an embodiment of the present invention. Wherein, FIG. 7F shows a container with an OHT 772, whose contents are being transferred by a robot 732 to an opener station (not shown). FIG. 7G shows then the overhead compartment walls 777 being removed via any method such as OHT such that the stack is bare at the opener station. FIG. 7H then displays the stack 722 containing substrates in an open and separated state.

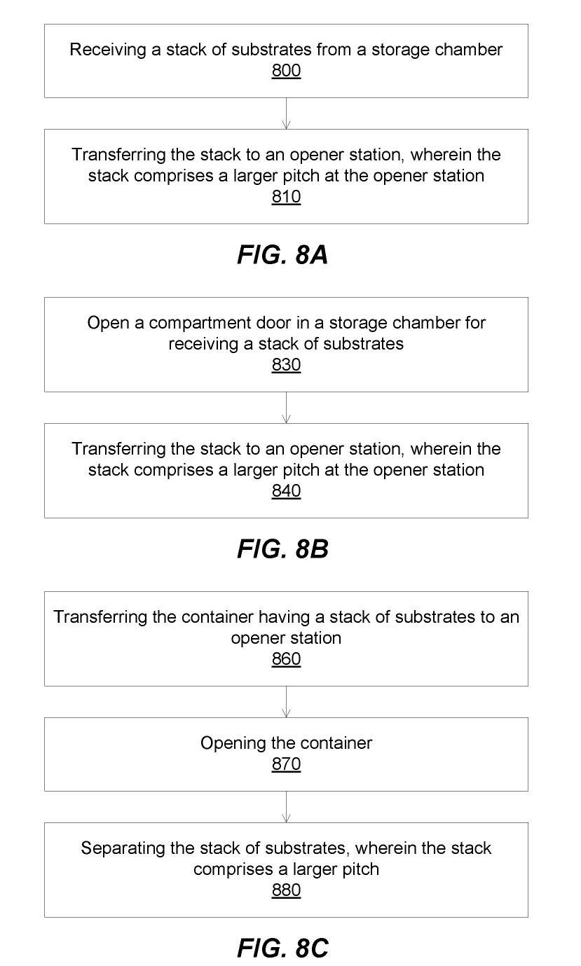

FIG. 8A describes a flow chart of an embodiment method for transferring substrates in a Tec-cell stocker system. Step 800 describes receiving a stack of closed substrates from a storage chamber. Step 810 describes transferring the received stack to an opener station for generating a stack of separated substrates with a larger pitch.

FIG. 8B describes a flow chart of an embodiment method for transferring substrates in a Tec-cell stocker system. Step 830 describes opening a compartment door in a storage chamber, for receiving a stack of closed substrates. Step 840 describes transferring the stack of closed substrates to an opener station for generating a stack of open substrates that has a larger pitch as compared to that of the stack of open substrates.

FIG. 8C describes a flow chart of an embodiment method for transferring substrates. Step 860 describes transferring the container having a stack of closed substrates to an opener station. In an embodiment, the container may be provided with an OHT. Step 870 describes opening the container and the process 880 describes separating/opening the stack of closed substrates, wherein the stack of separated substrates may comprise a larger pitch as compared to that of the stack of the closed substrates.

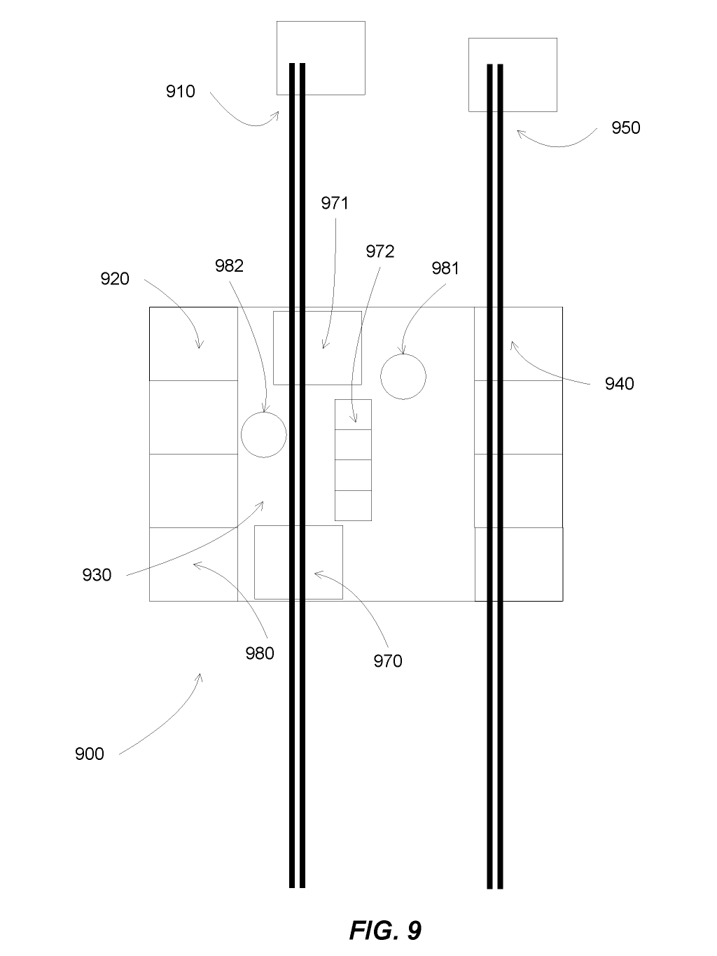

FIG. 9 depicts a top component view of a Tec-Cell stocker system 900, an embodiment of the present invention. Herein, an OHT system 910 is described for one or more Tec-Cell modules 920 stored in a storage chamber 930. In an embodiment, a Tec-cell module 920 may be a movable container configured for storing a stack of substrates in a collapsed state. The OHT system 910 may be configured for performing handover of the one or more Tec-cell modules 920 from top to down direction. Further, the Tec-cell modules and their contents such as substrates may be moved or manipulated by a robot, for example, a robot may be connected to a buffer station, or an opener station for transferring wafers to and from another containers such as FOUPs 940. In an embodiment, the FOUPs may also use an OHT system 950.

It is also noted there may be within the system, such as within the storage area, area or compartments, which may or may not be isolated, wherein gas or mechanicals may be stored, routed, reservoir or otherwise may provide an area for systems. There also may be auxiliary robots to transfer to or from OHT such as robot 981, as well as the robots in opener stations such as opener station 971, as well as dedicated OHT transfer stations such as 970. There also may be buffer stations within the system wherein containers, substrates, carriers, etc. may be held within the system for machine backlog, transfer backlog or for any reason. It is noted especially that any features may be shared across any embodiments.

In an embodiment, a high density container may be entered into the stocker 900 by OHT 910. The container may be entered into the transfer station 970 wherein then the transfer station 970 may include an opener system wherein then stacks of carriers and substrates, as well as individually, may then be accessed by a robot after being open wherein then they may put into a container held in opener station 971, wherein then robot 982, which may represent a plurality of robots ma then place the container held in opener station 971 into high density storage area 920. Additionally, then substrates and carriers may be accessed by robot 981 wherein then may be transferred in a similar process to a second, third or any plurality of stations with similar aspects such as OHT 950 with FOUPs or high density containers 940.

It is noted that robots 981 may be a single robot or a plurality of robots. It is noted in any embodiment that the robots may have different effectors wherein a robot may be designed to only carry, move or configured to a container such as a FOUP or low density container, or high density container such as a Tec-Cell, or may move stacks of carriers and substrates, or single carriers and substrates individually. It is noted too that in some embodiments the robots may have interchangeable or adjusting arms such that the same robot may interact with all aforementioned systems and elements.

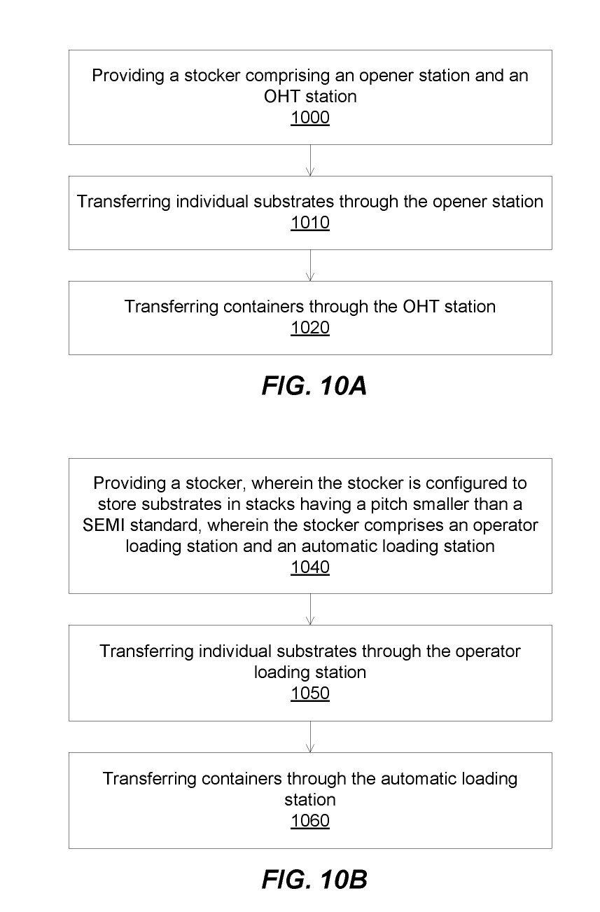

FIG. 10A describes a flow chart of an embodiment method for transferring substrates in a Tec-cell stocker system. Herein, step 1000 includes providing a stocker that comprises an opener station and an OHT station. Step 1010 includes transferring individual substrates through the opener station, and step 1020 includes transferring movable containers through the OHT station. In an embodiment, first a movable container is transferred to an opener station through the OHT station, then the substrates of the movable container are opened at the opener station, and thereafter, the individual substrates are transferred between the opener station and a load port. It may be noted, that the load port may be airtight, provide for all standard connections, such that the transfer is done in a sterile environment with limited or no contaminations.

FIG. 10B describes a flow chart of an embodiment method for transferring substrates in a Tec-cell stocker. Herein, step 1040 includes providing a stocker, wherein the stocker is configured to store substrates in stacks having a pitch smaller than a SEMI standard, and wherein the stocker comprises an operator loading station and an automatic loading station. The operator loading station is a port/terminal which is accessible by human manual entry. The operator loading station is a port which can be accessed by a machine transfer mechanism. Step 1050 includes transferring individual substrates through the operator loading station, and step 1060 includes transferring containers through the automatic loading station. It is noted this may be done partially as aforementioned.

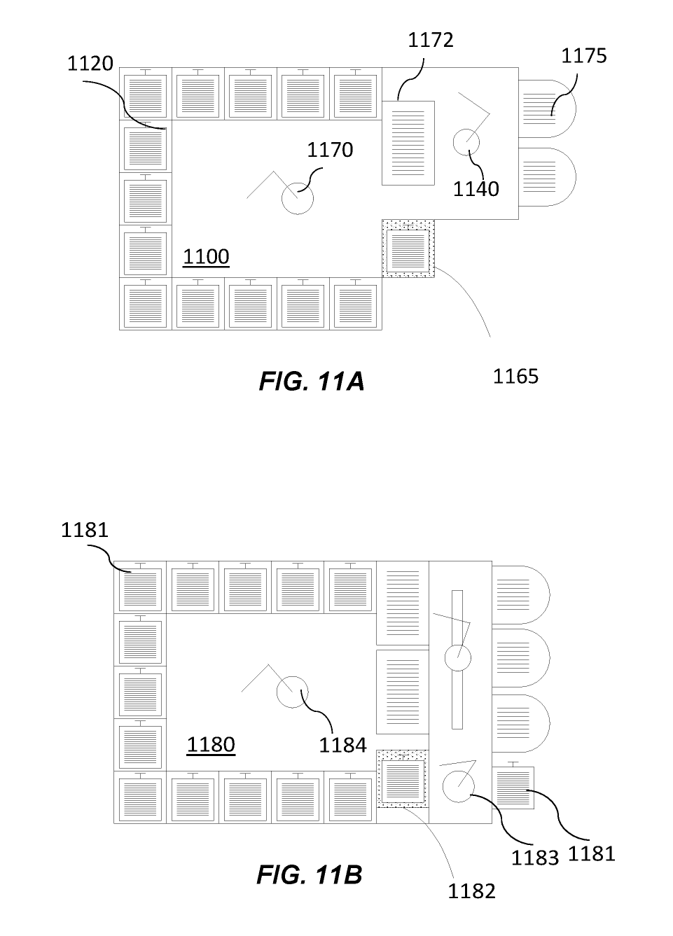

FIG. 11A depicts a top component view of Tec-Cell transfer in a Tec-cell stocker, in an embodiment of the present invention. Herein, a stocker is described that includes a storage chamber 1100 which includes one or more movable containers 1120 (with OHT) for storing one or more substrates, with a combination of low density and high density loader stations. In an embodiment, the stocker includes a stand-alone load port with or without an EFEM for single substrate transfer from an opener station 1172 to one or more FOUPs 1175. In another embodiment, an operator may access a container load port 1165 for container transfer, wherein a storage robot 1170 can pick up a container to be transferred to the storage chamber 1100. It may be noted that the load port 1165 may either be manually or automatically accessed, for accessing buffer or other system providing wafers, Tec-Cell's or other materials.

FIG. 11B depicts a top component view of Tec-Cell transfer in a Tec-cell stocker, in an embodiment of the present invention. The Tec-cell stocker includes a storage chamber 1180 that includes one or more movable containers 1181 (with OHT) of closed substrates. Herein, an EFEM load port 1182 is described for individual substrate transfer as well as container transfer. In an embodiment, an EFEM robot 1183 can transfer a container 1181 to the container load port 1182, wherein a storage robot 1184 can pick up the container from the container load port 1182, to be transferred to the storage area 1180 or any other area of the chamber.

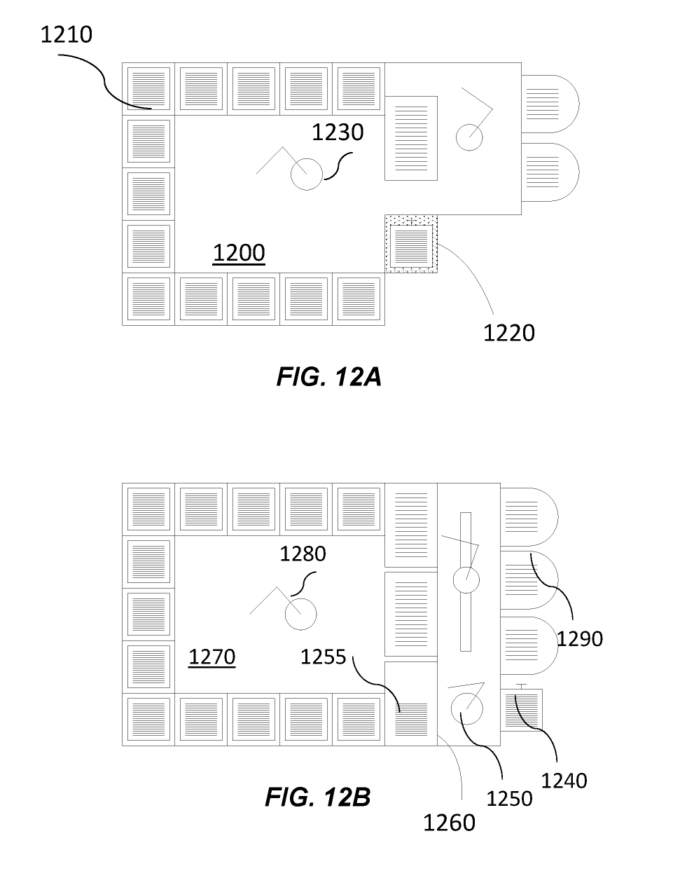

FIG. 12A depicts a top component view of a Tec-Cell transfer in a Tec-Cell stocker, in an embodiment of the present invention. The Tec-cell stocker includes a storage chamber 1200 with one or more containers 1210, a combination of low density and high density loader stations, a bare stack (with or without compartment/door), and a standalone load port 1220 with no EFEM or in some embodiments with EFEM for single substrate transfer. It is noted that an operator or other mechanism may access the container load port 1210 for accepting a container. In an embodiment, in the container load port 1220, the container can be opened, and a storage robot 1230 can pick up the whole stack to be transferred to the storage chamber 1200

FIG. 12B depicts a top component view of Tec-Cell transfer in a Tec-cell stocker, in an embodiment of the present invention. An EFEM is described for individual substrate transfer and container transfer. In the container load port 1240, the container can be open, and an EFEM robot 1250 can pick up the whole stack 1255 to be transferred to an opener station 1260. In an embodiment, the whole stack 1255 can be transferred to a storage chamber 1270 by a storage robot 1280. In another embodiment, upon opening of the stack 1255 of substrates at the opener station 1260, the EFEM individual robot 1250 can transfer individual substrates from the opener station 1260 to FOUPs or other containers 1290

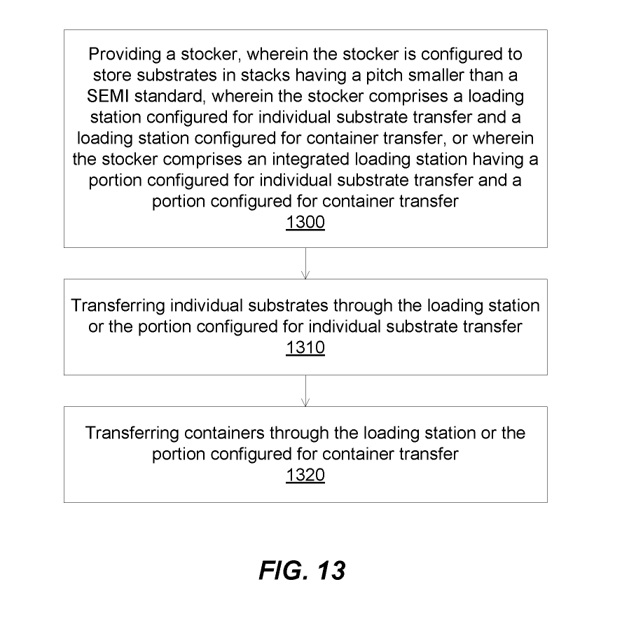

FIG. 13 describes a flow chart of an embodiment method for transferring and loading of stack of substrates in a Tec-cell stocker. Herein, step 1300 discloses providing a stocker, wherein the stocker is configured to store substrates in stacks having a pitch smaller than a SEMI standard, wherein the stocker comprises a loading station configured for individual substrate transfer, and a loading station configured for container transfer, and wherein the stocker comprises an integrated loading station having a portion configured for individual substrate transfer and a portion configured for container transfer. Step 1310 describes transferring individual substrates through the loading station or the portion configured for individual substrate transfer, and step 1320 discloses transferring containers through the loading station or the portion configured for container transfer. In an embodiment, the two loading stations, one with a robot for single substrate handling, and one with a robot for container handling may be replaced, or may provide auxiliary service to an OHT system as aforementioned. There may be also any plurality of stations, robots, for any of the purposes or needs.

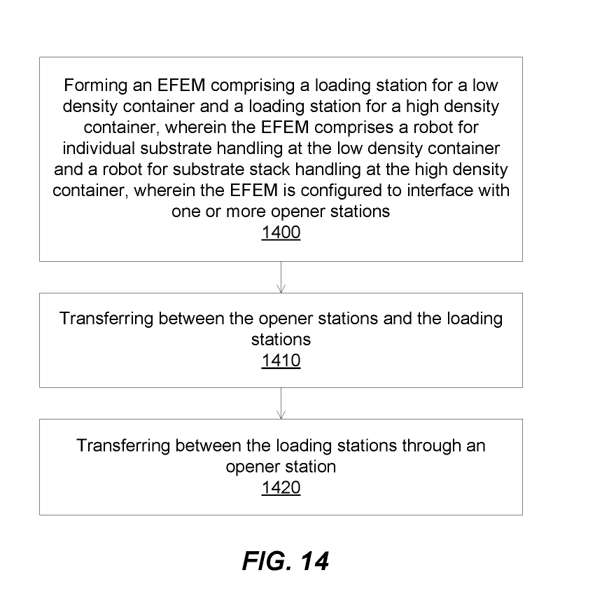

FIG. 14 describes a flow chart of an embodiment method for transferring and loading with different containers. Herein, step 1400 includes forming an EFEM that comprises a loading station for a low density container and a loading station for a high density container, wherein the EFEM comprises a robot for individual substrate handling at the low density container and a robot for substrate stack handling at the high density container, and wherein the EFEM is configured to interface with one or more opener stations. Step 1410 describes transferring substrates between the opener stations and the loading stations. Step 1420 describes transferring substrates between the loading stations through an opener station.

It will be apparent to one of ordinary skill in the art that EFEM may be different for different type of containers and FOUPs, etc. such that the EFEM may match the intended use, or may be actively able to adapt to use with different containers. This is also to be noted to be used as a broader ability than OHT and may supplement, be instead of OHT, among other methods or systems.

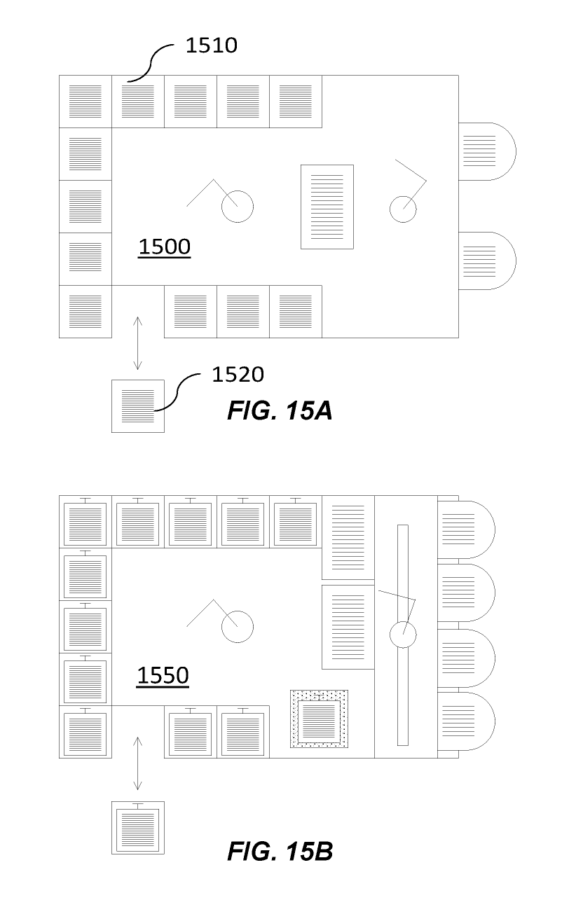

FIG. 15A depicts a top component view of Tec-Cell transfer with robot and removable components, in a Tec-cell stocker, in an embodiment of the present invention. Herein, a stocker is being described that has a storage chamber 1500 with removable containers 1510, wherein each container may include a stack, or at least one bare wafer, or may be empty. A container 1520 may be removed from the chamber 1500 so as to be serviced, moved, or to be provided in another system. In an embodiment, each container 1510 may have a door so as to isolate it from outside ambient when being removed from the chamber 1500, such that the containers can be removed without contamination, and during constant use.

FIG. 15B depicts a top component view of a Tec-Cell transfer with robot and removable components, in an embodiment of the present invention. Herein, a storage chamber 1550 includes one or more containers 1560 with OHT.

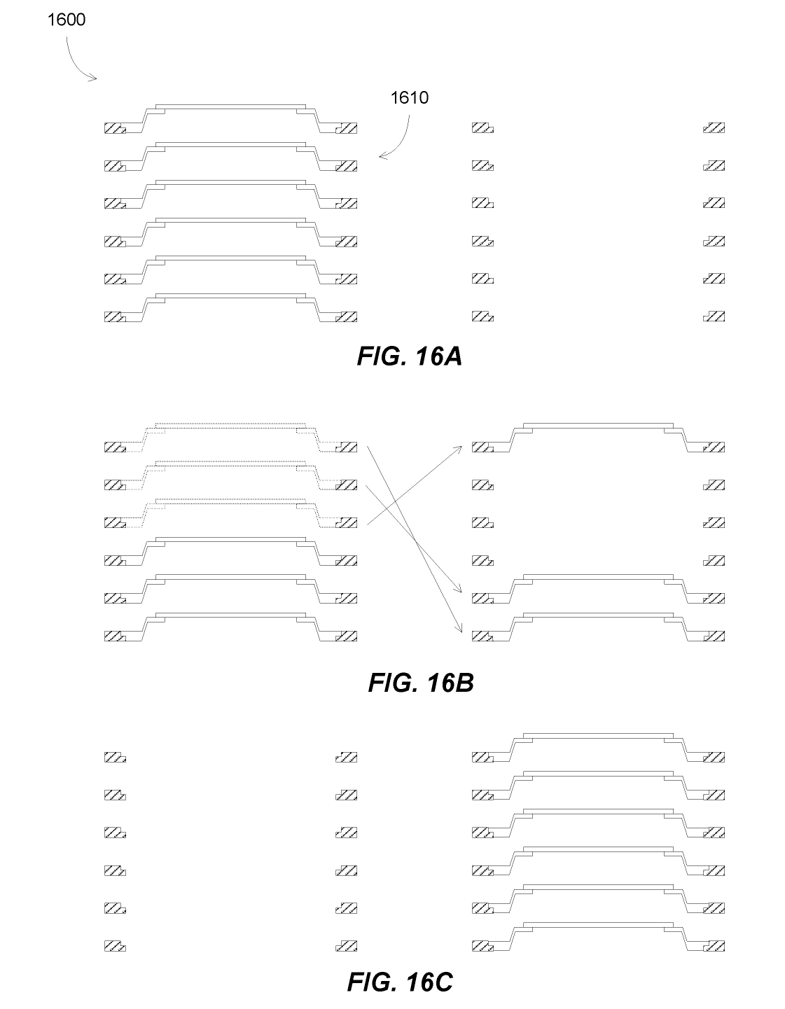

FIGS. 16A, 16B and 16C are profile views of a Tec-Cell, in an embodiment of the present invention.

FIG. 16A illustrates a stack 1600 of one or more substrates/wafers supported on respective Tec-cell carriers. Herein, a sorter (not shown) implemented through a robot may be configured for moving a wafer from a first position 1610 to a second position 1620 within the stack 1600.

FIG. 16B shows the moving of wafers from the first position to the second position for sorting, but in different parts or orders of the stack. It may be noted that this movement of wafers for sorting may be done by any robot, in any order or in any process, and the wafers may move between any plurality of positions, stacks and directions. In an embodiment, the sorter may sort a wafer by moving respective carrier. Further, sorting can be done only for wafers that are in an open state in respective stack.

FIG. 16C shows a random sorter wherein the opener is open to all slots, but in other embodiment, some slots may need to be opened.

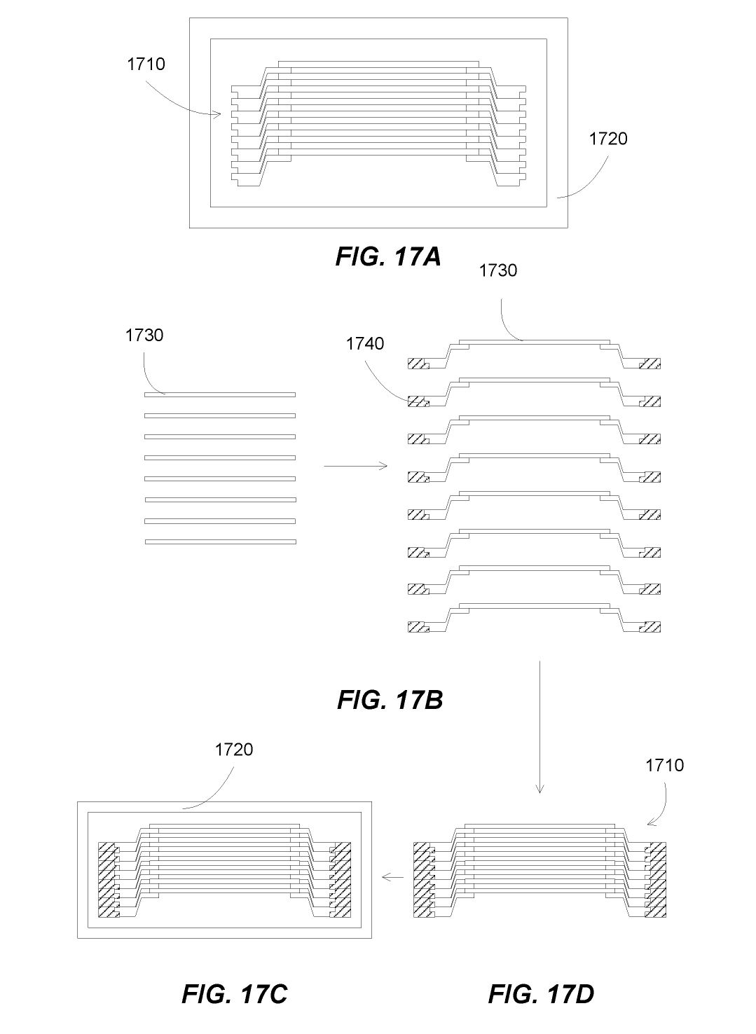

FIGS. 17A, 17B, 17C and 17D are profile views of a Tec-Cell that includes a container for storage, in an embodiment of the present invention.

FIG. 17A illustrates a stack 1710 of substrates and Tec-Cell carriers condensed into Tec-Cell high density configuration and stored in a storage container 1720. It may be noted that the wafers, Tec-cells, carriers and stacks may be of any plurality.

FIG. 17B shows substrates 1730 that are transferred from FOUPs to Tec-Cell carriers 1740, wherein the substrates are shown to be in an open position.

FIG. 17C then shows the stack 1710 in a closed position on Tec-Cell carriers.

FIG. 17D shows the stack 1710 stored in the container 1720 in a closed position. It may be noted, that the stack 1710 may be moved to the container 1720 by any known method.

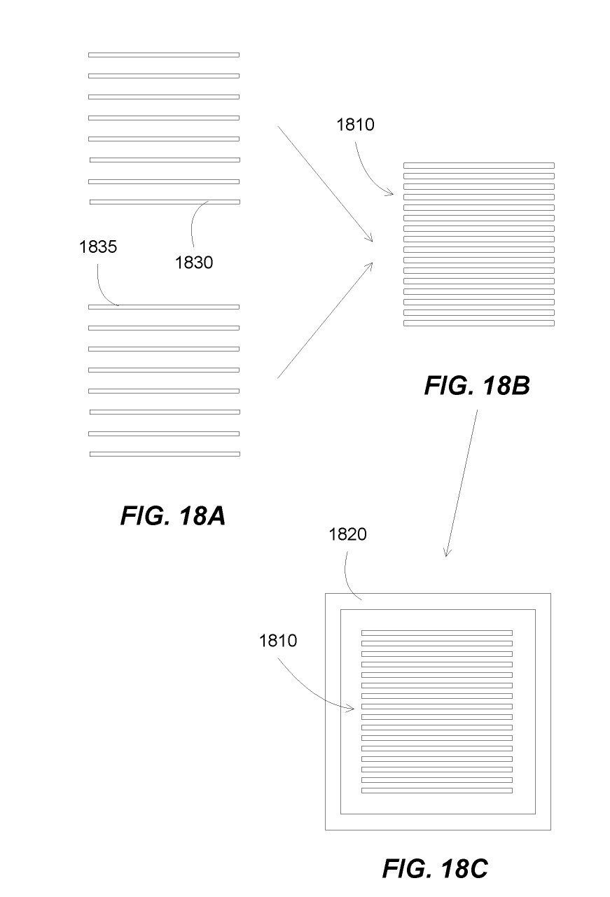

FIGS. 18A, 18B and 18C are profile views of a Tec-Cell, in an embodiment of the present invention.

FIG. 18A shows first and second stacks 1830 and 1835 of wafers in their respective FOUPs, and wherein the first and second stacks 1830 and 1835 may be combined together to be stacked in a high capacity Tec-Cell carrier as a single stack 1810.

FIG. 18B shows the aforementioned combined stack 1810 of wafers wherein a stack 1830 for instance and a stack 1835 may be combined by a robot or other methods into a stack. It is noted that the stack may have a higher density with lower pitch or smaller distance between the carriers and substrates than the separate stacks before.

FIG. 18C shows the combined stack 1810 in high density form, positioned within a high density container or storage 1820.

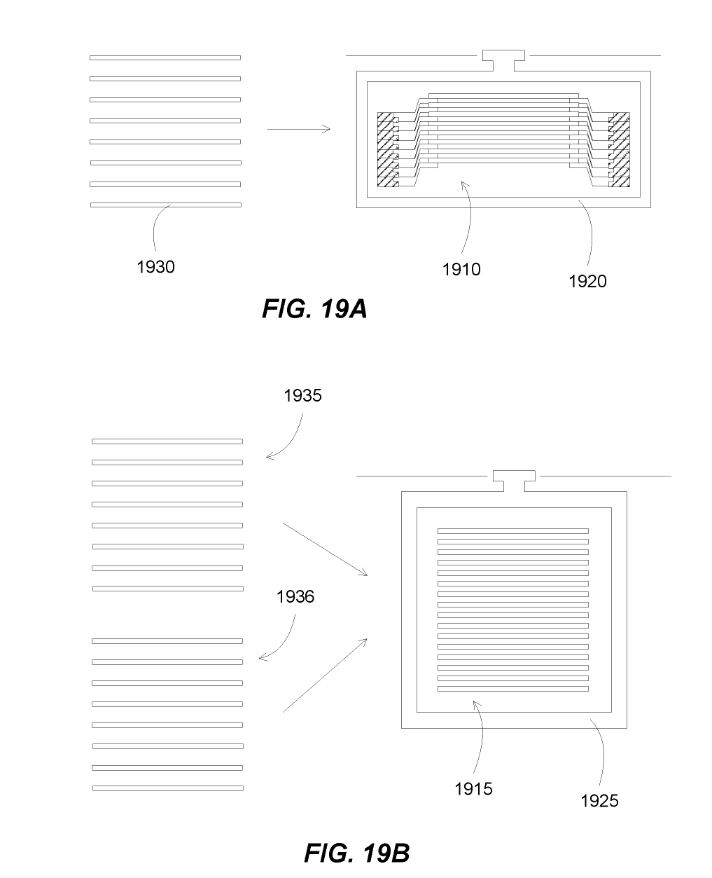

FIGS. 19A and 19B are profile views of a Tec-Cell, in an embodiment of the present invention.

FIG. 19A shows a stack 1930 of wafers from any source that may be converted into a high density stack 1910, put on Tec-Cell carriers, and then placed in a Tec-cell container 1920, that may include an OHT or any other transport abilities.

FIG. 19B shows first and second stacks 1935 and 1936 which may be combined into one stack 1915 of Tec-Cell high density carriers, and are positioned such that it may be contained in a container 1925 which may have OHT or other transportation abilities.

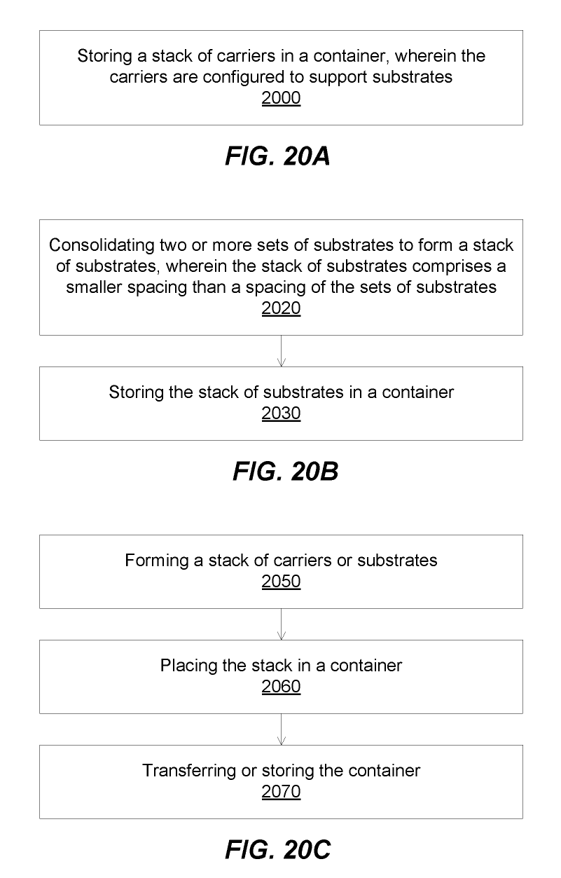

FIGS. 20A and 20B describe a flow chart of an embodiment method for transferring and loading substrates in a Tec-cell.

FIG. 20A describes a process 2000 which includes storing a stack of carriers in a container, wherein the carriers are configured to support substrates.

FIG. 20B describes a process 2020 which includes consolidating two or more sets of substrates to form a combined stack of substrates, wherein the combined stack of substrates has a pitch smaller than that of the two or more sets of substrates. Process 2030 includes storing the combined stack of substrates in a container.

FIG. 20C includes a process 2050, which includes forming a stack of carriers or substrates. Process 2060 includes placing the stack in a container, and process 2070 includes transferring or storing the container.

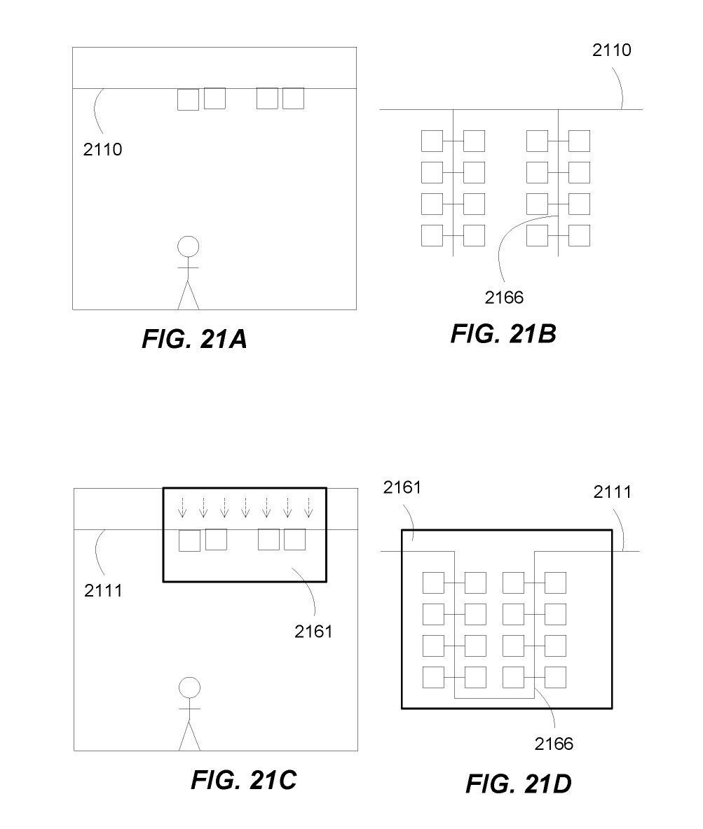

FIGS. 21A, 21B, 21C and 21D describe a side component view of a ceiling based transport mechanism of a Tec-Cell stocker system, in an embodiment of the present invention. FIGS. 21A, 21B, 21C and 21D may describe a Stocker with a distributed OHT stack.

FIGS. 21A and 21B describes an OHT track stocker system as storage system for Tec-Cell containers. A main OHT track 2110 may be formed, so that one or more containers may be stored at one or more branch tracks 2166, and may be moved in a horizontal direction through the main OHT track 2110. In an embodiment, the containers store high density Tec-Cell containers. In another embodiment, the containers store FOUPs.

FIGS. 21C and 21D may describe an OHT track stocker system as a storage system 2161, (wherein the main OHT track 2111 may follow a high density storage track 2166 within the storage system 2161. In an embodiment, there may be a laminar flow of purging gas in the storage system 2161 for removal of contaminants. Thus, the storage system 2161 may be a purged enclosure mounted on a ceiling that encloses a distributed OHT track system.

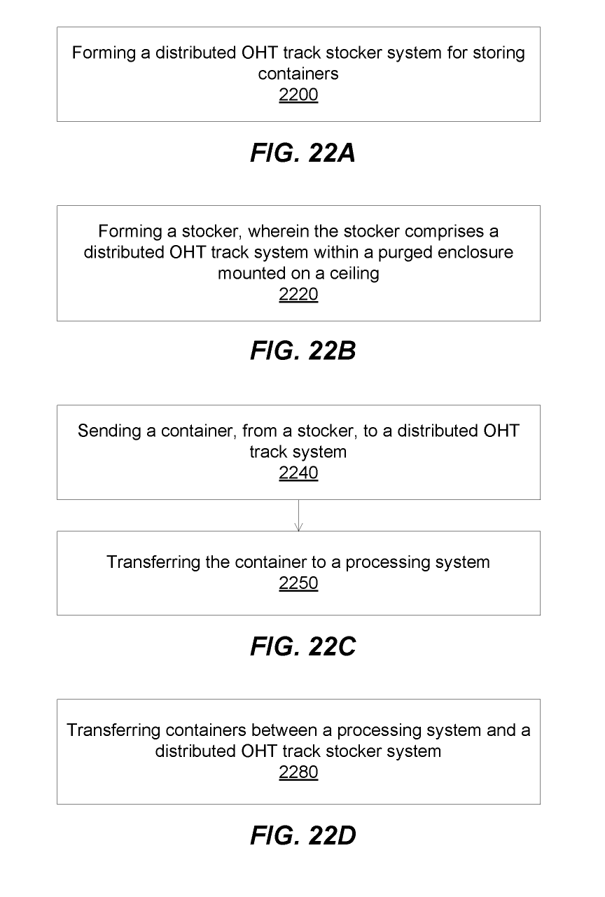

FIGS. 22A, 22B, 22C and 22D describe a flow chart of an embodiment of the present invention ceiling based transport system, for FOUPs and high-density Tec-Cells, as well for using the OHT stocker as a temporary storage.

FIG. 22A describes at least one process 2200 for a distributed OHT track stocker system for storing containers.

FIG. 22B describes at least one process 2220 for forming a stocker, wherein the stocker comprises a distributed OHT track system within a purged enclosure mounted on a ceiling.

FIG. 22C describes at least one process 2240 for sending a container, from a stocker, to a distributed OHT track system and process 2250 includes transferring the container to a processing system.

FIG. 22D describes at least one process 2280 for transferring containers between a processing system and a distributed OHT track stocker system.

A number of embodiments have been described. Nevertheless, it will be understood that various modifications may be made without departing from the spirit and scope of the claimed invention. In addition, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other embodiments are within the scope of the following claims.

It may be appreciated that the various systems, methods, and apparatus disclosed herein may be embodied in a machine-readable medium and/or a machine accessible medium compatible with a data processing system (e.g., a computer system), and/or may be performed in any order.

The structures and modules in the figures may be shown as distinct and communicating with only a few specific structures and not others. The structures may be merged with each other, may perform overlapping functions, and may communicate with other structures not shown to be connected in the figures. Accordingly, the specification and/or drawings may be regarded in an illustrative rather than a restrictive sense.

What is claimed is:

1. A substrate stocker system, comprising:
a high density storage chamber that comprises one or more high density containers or stacks of one or more substrates, each substrate being supported on a respective carrier wherein the high density containers or stacks are in a closed position;
one or more low density containers, each low density container being configured to store one or more substrates and carriers;
one or more opener stations, each opener station configured to send or receive one or more stacks or containers from at least one high density storage chamber and one or more substrates from the low density containers, each opener station comprising one or more separator modules for changing one or more distances between corresponding one or more adjacent substrates in the high density containers or stacks;
at least one robot wherein the one or more robots are configured to move:
one or more containers or stacks between the high density storage chamber, and the one or more opener stations; and
one or more substrates between the one or more high density open position high density containers or stacks and the one or more low density containers.

2. The substrate stocker system as claimed in claim 1, wherein each low density container is a Front Opening Unified Pod (FOUP).

3. The substrate stocker system as claimed in claim 1, wherein one or more distances between one or more adjacent substrates of the one or more stacks in the closed position, is less than a threshold distance defined by Semiconductor Equipment and Materials International (SEMI) standard.

4. The substrate stocker system as claimed in claim 1 further comprising a first OHT system, and one or more OHT stations, for moving one or more movable high density containers with the OHT, between the high density storage chamber and external to the stocker system.

5. The substrate stocker system as claimed in claim 4 further comprising a container load port configured to receive and store at least movable container with the OHT, wherein the first robot is configured to transfer the movable container with the OHT, from the container load port to the high density storage chamber.

6. The substrate stocker system as claimed in claim 1 further comprising a second OHT system, for moving one or more low density containers to and from the stocker system.

7. The substrate stocker system as claimed in claim 1 further comprising an Equipment Front End Module (EFEM) coupled to the one or more opener stations, wherein the second robot is disposed within the EFEM module for moving one or more substrates and carriers from an open position high density carrier, between the one or more opener stations, and the one or more low density containers.

8. The substrate stocker system as claimed in claim 7, wherein the EFEM module further comprises a third robot for transferring a movable container with the OHT from a container load port to the high density storage chamber.

9. The substrate stocker system as claimed in claim 8, wherein the third robot is configured to access the movable container by opening a side of the container at the container load port, and transfer carriers and substrate stack to an opener station.

10. The substrate stocker system as claimed in claim 1 further comprising at least one of:
an operator loading station configured to enable transfer of one or more substrates and carriers to and from the one or more opener stations; and
an automatic loading station configured to enable automatic transfer of one or more substrates and carriers to and from the high density storage chamber.

11. The substrate stocker system as claimed in claim 10 further comprising:
wherein the substrates and carriers entered into the operator or automatic loading station are in high density containers in an open position.

12. The substrate stocker system as claimed in claim 10 further comprising:
wherein the substrates and carriers entered into the operator or automatic loading station are in high density containers in a closed position

13. The substrate stocker system as claimed in 1, further comprising a purged enclosure mounted on a ceiling therein, wherein the purged enclosure comprises a distributed OHT tracker system that has a main OHT track and one or more branch tracks for storing one or more movable containers.

14. A method of storing and transferring substrates in a substrate stocker system, the method comprising:
transferring a first closed stack or container of one or more carriers and substrates to or from a high density storage chamber and at least one opener station by an at least one robot;
opening or closing the stack or container at the opener station, wherein opening increases the distances between each carrier and substrate and closing decreases the distances between each carrier and substrate; and
transferring the one or more opened individual substrates to or from at least one of: a low density container, one or containers of an Equipment Front End Module (EFEM), or an external dock cart.

15. The method as claimed in claim 14, further comprising:
moving a movable high density container to or from a container load port and an opener by an at least one robot;
opening or closing the moveable container
transferring a stack or individual carries and substrates to or from the first high density container and the moveable high density container;

16. The method as claimed in claim 14, further comprising sorting one or more substrates within the respective stack or container by moving the one or more substrates among one or more positions within the stack.

17. The method as claimed in claim 15, further comprising sorting one or more carriers and substrates or stacks by changing the position when transferring the carriers and substrates or stacks between the first high density container and the moveable high density container.

18. The method as claimed in claim 14 further comprising:
moving a movable high density container from a container load port to high density storage chamber by at least one robot.

19. The method as claimed in claim 14 further comprising:
combining a first stack of carriers and substrates and a second stack of carriers and substrates from at least one of: a low density container, one or containers of an Equipment Front End Module (EFEM), a high density container or an external dock cart to form a combined stack, wherein the combined stack has a pitch smaller than pitches of each of the first and second stacks; and
wherein the combined stack is in at least one of: a high density movable container to be moved by OHT or via a container load ports to a dock cart or external system, or a high density container to be stored in the high density storage chamber.

20. The method as claimed in claim 17 further comprising:
forming a distributed OHT track stocker system for storing high density containers, wherein the distributed OHT track stocker system is formed within a purged enclosure mounted on a ceiling therein; and
transferring a high density container from the high density storage area to a distributed OHT track system.
